(19) United States
(12) Patent Application Publication
(10) Pub. No.: US 2018/0239102 A1
(43) Pub. Date: Aug. 23, 2018

(54) OPTICAL MOUNT

(71) Applicant: Corning Incorporated, Corning, NY (US)

(72) Inventors: Robert Dennis Grejda, Fairport, NY (US); Keith Ernest Hanford, Macedon, NY (US); Brian Monroe McMaster, Pittsford, NY (US); Todd Robert McMichael, Rochester, NY (US); Matthew Roland Millecchia, Fairport, NY (US); James Edward Platten, Penfield, NY (US)

(21) Appl. No.: 15/880,117

(22) Filed: Jan. 25, 2018

Related U.S. Application Data
(60) Provisional application No. 62/460,936, filed on Feb. 20, 2017.

(51) Int. Cl. G02B 7/00; G02B 7/18; G02B 7/182; B29C 33/00; G02B 7/02; G03F 7/20

(52) U.S. Cl. CPC G02B 7/003; G02B 7/181; G02B 7/1822; G03F 7/70833; G02B 7/026; G02B 7/008; B29C 33/005

(57) ABSTRACT

An optical mount includes a support substrate defining an aperture configured to receive an optical element. A support assembly is positioned proximate a perimeter of the aperture. The support assembly includes a resilient member configured reflects in response to relative motion between the optical element and the support substrate. A support plate is positioned on the resilient member and is in contact with the optical element.

This application claims the benefit of priority under 35 U.S.C. § 119 of U.S. Provisional Application Ser. No. 62/460,936 filed on Feb. 20, 2017 the content of which is relied upon and incorporated herein by reference in its entirety.

### FIELD OF THE DISCLOSURE

The present disclosure generally relates to optical mounts, and more particularly to optical mounts for holding optical elements.

### BACKGROUND

Optical mounts are used to hold optical elements during the deposition of thin films on the optical elements. Deposition of the thin films typically occurs at high temperatures and high vacuum (e.g., greater than about 500° K and about 0.0001 mbar). Differences in the coefficient of thermal expansion of the optical elements and the optical mounts may result in the generation of stresses as the optical mounts transition from room temperature to a process temperature. Such stresses may result in damage to the optical elements and/or the optical mount.

### SUMMARY OF THE DISCLOSURE

According to at least one embodiment of the present disclosure, an optical mount includes a support substrate defining an aperture configured to receive an optical element. A support assembly is positioned proximate a perimeter of the aperture. The support assembly includes a resilient member configured to flex in response to relative motion between the optical element and the support substrate. A support plate is positioned on the resilient member and is in contact with the optical element.

According to another embodiment of the present disclosure, an optical mount includes a support substrate defining an aperture configured to receive an optical element. The support substrate defines a plurality of wells around a perimeter of the aperture. A support assembly is positioned within each of the wells. The support assemblies include a support plate configured to contact the optical element and a resilient member configured to allow movement of the support plate within the well.

According to another embodiment of the present disclosure, an optical mount including a support substrate defining an aperture configured to receive an optical element. A plurality of support assemblies is positioned around the perimeter of the aperture. The support assemblies include a resilient member configured to flex in response to relative motion between the optical element and the support substrate. The resilient member as integrally defined by the support substrate. A support plate is positioned on a resilient member and is in contact with the optical element.

According to another embodiment of the present disclosure, a method includes the steps of: positioning an optical element on a support assembly of a support substrate; drawing a vacuum around the support substrate and optical element; heating the support substrate and optical element; flexing a resilient member of the support assembly in response to relative motion between the optical element and the support substrate; and depositing a film on an optical surface of the optical element.

These and other features, advantages, and objects of the present disclosure will be further understood and appreciated by those skilled in the art by reference to the following specification, claims, and appended drawings.

### BRIEF DESCRIPTION OF THE DRAWINGS

The following is a description of the figures in the accompanying drawings. The figures are not necessarily to scale, and certain features and certain views of the figures may be shown exaggerated in scale or in schematic in the interest of clarity and conciseness.

FIG. 1A is a top perspective view of an optical mount, according to one embodiment;

FIG. 1B is a top perspective view of the optical mount of FIG. 1A holding an optical element, according to one embodiment;

FIG. 1C is a cross-sectional view taken at line IC of FIG. 1B;

FIG. 2A is a top perspective view of an optical mount, according to one embodiment;

FIG. 2B is a top perspective view of the optical mount of FIG. 2A holding an optical element, according to one embodiment;

FIG. 2C is a cross-sectional view taken at line IIC of FIG. 2B;

FIG. 3A is a top perspective view of an optical mount, according to one embodiment;

FIG. 3B is a top perspective view of the optical mount of FIG. 3A holding an optical element, according to one embodiment;

FIG. 3C is a cross-sectional view taken at line IIIC of FIG. 3B;

FIG. 4A is a top perspective view of an optical mount, according to one embodiment; and

FIG. 4B is a cross-sectional view taken at line IVB of FIG. 4B.

### DETAILED DESCRIPTION

Additional features and advantages of the invention will be set forth in the detailed description which follows and will be apparent to those skilled in the art from the description, or recognized by practicing the invention as described in the following description, together with the claims and appended drawings.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions.

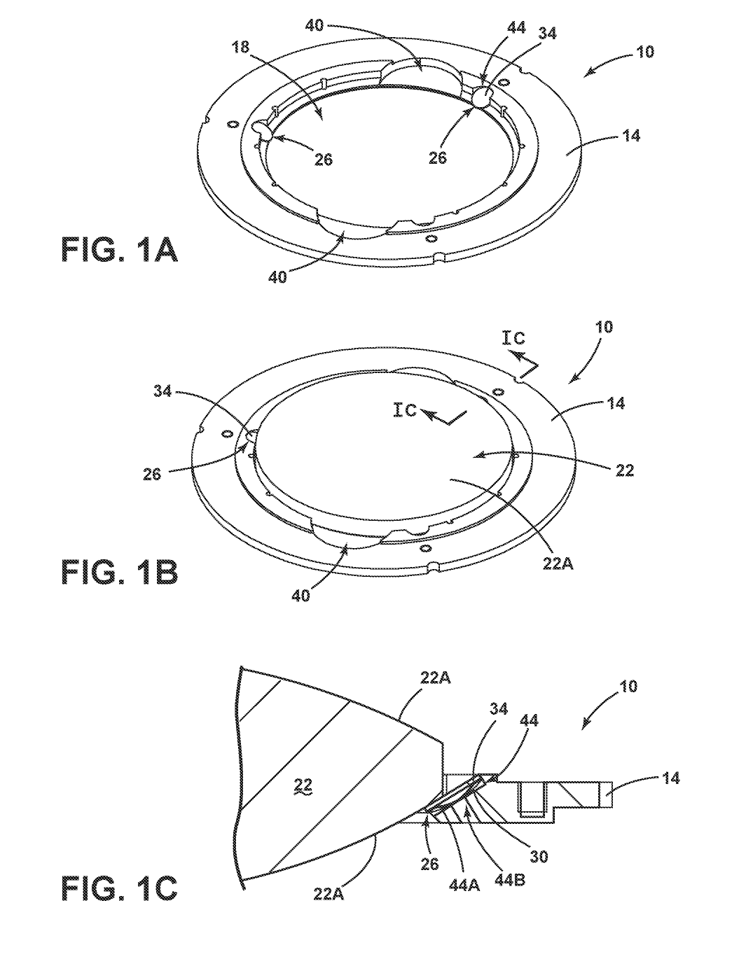

Referring now to FIGS. 1A-4B, depicted is an optical mount 10 including a support substrate 14 which defines an aperture 18 configured to receive an optical element 22. A support assembly 26 is positioned proximate a perimeter of the aperture 18. The support assembly 26 includes a resilient member 30 configured to flex in response to relative motion between optical element 22 and the support substrate 14. A support plate 34 is positioned on the resilient member 30.

Referring now to FIGS. 1A-C, the support substrate 14 of the optical mount 10 is configured to support the optical element 22 during a thin film or coating deposition process. According to various examples, the optical mount 10 may be used in the deposition of a thin film in conjunction with a vacuum and/or high temperatures. The film or coating may be applied in a single or multiple thin layers to provide various optical characteristics such as antireflection and/or spectral or lightwave filtering. The film or coating may be applied to an optical surface 22A of the optical element 22. Although described herein with respect to a single optical mount 10, a plurality of optical mounts 10 may be used in conjunction with one another such that a plurality of optical elements 22 may have films deposited thereon substantially simultaneously.

In the depicted example, the support substrate 14 of the optical mount 10 is substantially circular, but it will be understood that the support substrate 14 may take a variety of shapes and configurations in order to support the optical element 22. For example, the support substrate 14 may be substantially oval, oblong, square, rectangular, or higher order polygons. The support substrate 14 may have a diameter, or longest length, of between about 50 mm and about 150 mm, or between about 80 mm and about 120 mm. In a specific example, a diameter of the support substrate 14 may be about 100 mm. The aperture 18 is sized and shaped to allow the support substrate 14 to receive the optical element 22. The aperture 18 may have a diameter, or longest length, of between about 20 mm and about 50 mm, or between about 30 mm and about 40 mm. In a specific example, the aperture 18 may have a diameter of about 35 mm. Although depicted as substantially circular, the aperture 18 may take a variety of shapes in order to support a variety of optical element 22 shapes. Further, it will be understood that although the shape of the aperture 18 is substantially the same as that of the support substrate 14 (i.e., both the support substrate 14 and the aperture 18 are circular), the shape of the aperture 18 may be different than that of the support substrate 14. For example, the aperture 18 may be substantially square while the support substrate 14 may be generally circular. Even further, it will be understood that the shape of the aperture 18 may differ from that of the optical element 22. For example, the optical element 22 may be triangular and the aperture 18 may be substantially circular. It will be understood that the support substrate 14 and the aperture 18 may take any size which is suitable to support a desired optical element 22.

The support substrate 14 may be composed of a metal, a ceramic, a glass, a glass-ceramic and/or combinations thereof. In metallic examples of the support substrate 14, the metal may be aluminum, stainless steel, ferrous metals, non-ferrous metals and/or other metals which are substantially unreactive with the optical element 22. It will be understood that plastics, polymers and/or other materials compatible with high temperature/high vacuum deposition processes can also be used as the base material of the support substrate 14.

The support substrate 14 may define a plurality of placement features 40 positioned around a perimeter of the aperture 18. The placement features 40 may be generally recessed into the support substrate 14 and be configured to aid in the placement and removal of the optical element 22 from within the support substrate 14. For example, the placement features 40 may be recessed to allow an operator to accurately place the optical element 22 into the support substrate 14 by hand. Although depicted as having two placement features 40, the support substrate 14 may define a single placement feature 40, or greater than two placement features 40 without departing from the teachings provided herein.

The optical element 22 may be a lens or other translucent or transparent substrate.

Further, the optical element 22 may be composed of an opaque material which is transparent or translucent to non-visible wavelengths of the electromagnetic spectrum (e.g., infrared, ultraviolet, etc.). In circular examples of the optical element 22, a diameter of the optical element 22 may be between about 20 mm and about 50 mm, or between about 30 mm and about 40 mm. In a specific example, the optical element 22 may have a diameter of about 35 mm. The optical element 22 defines at least one optical surface 22A. The optical services 22A of the optical element 22 may take a variety of shapes including biconvex, concave, concave/convex, planar, concave/concave and/or combinations thereof. According to a specific example, the optical element 22 may be a lens configured to direct high-power ultraviolet through infrared light to a target such as in microlithography for microcircuit fabrication and/or in semiconductor inspection. The optical element 22 may be composed of a glass, glass-ceramic, or ceramic material. The optical element 22 may have an amorphous or a crystalline structure. According to one example, the optical element 22 may be composed of a crystalline material such as calcium fluoride (CaF₂). According to another example, the optical element may be composed of magnesium fluoride (MgF₂). Use of calcium fluoride and/or magnesium fluoride as the material of the optical element 22 may be advantageous in that it provides low dispersion and/or high bandwidth capability for handling intense ultraviolet and/or infrared radiation. The optical element 22 may be polished or unpolished on the one or more optical surfaces 22A. The aforementioned films and/or coatings may be positioned on the one or more optical surfaces 22A.

One or more wells 44 are defined within and by the support substrate 14. The wells 44 are defined around, or proximate, a perimeter of the aperture 18. In the depicted example, the support substrate 14 defines three wells 44, but it will be understood that as few as a single well 44 may be defined and greater than three wells 44 may be defined. In order to deterministically control the location of the optical element 22 in the support substrate 14, three contact points (e.g., the support assemblies 26) may be chosen. The wells 44 are depicted as having a substantially circular cross-sectional shape, but it will be understood that the cross-sectional shape of the wells 44 may be oblong, square, rectangular, or higher order polygons.

A support assembly 26 is positioned within each of the wells 44. Use of the support assembly 26 allows the location nature of the contact between the support substrate 14 and the optical element 22 to be predefined rather than relying on machining tolerances, surface structure, and/or finishes to define the contact location. In other words, the exact contact points between the optical element 22 in the substrate 14 are known rather than varying from optical mount 10 to optical mount 10 based on the particular machine characteristics of that mount 10. Each of the wells 44 defines a bottom surface 44A which is in contact with the support assembly 26. Each of the wells 44 includes a channel 44B. The channels 44B are defined through the support substrate 14 such that the channels 44B fluidly couple each of the wells 44 within an underside of the support substrate 14. The channels 44B may fluidly couple to each of the wells 44 at the bottom surface 44A. Use of the channels 44B may be advantageous in allowing gasses present within the well 44 and building beneath the support plate 34 to easily pass out of the support substrate 14 as the optical mount 10 is placed under a vacuum. In other words, use of the channel 44B may prevent the wells 44 from being blind openings.

The support plate 34 of the support assembly 26 is positioned on top of the resilient member 30. The support plate 34 is configured to contact one of the optical services 22A of the optical element 22. The support plates 34 may be positioned within the wells 44 such that the support plate 34 is proud into the aperture 18. In other words, the support plate 34 may be configured to protrude slightly into the aperture 18. According to various examples, the support plate 34 may be the only component of the optical mount 10 which contacts the optical element 22. The location of the support plate 34 of the support assembly 26 is designed to contact the optical element 22 near the outside perimeter or edge of the optical surface 22A. The contact area of the support plate 34 and the optical surface 22A is designed to be nominally tangent to the optical surface 22A of the optical element 22 at the point of contact. According to various examples, the support plates 34 may be the only structure of the optical mount 10 which the optical element 22 contacts. In other words, the optical element 22 may not contact or touch the support substrate 14.

The support plate 34 may be composed of a ceramic, metal matrix composite, glass, glass-ceramic, and/or combinations thereof. According to various examples, the support plate 34 may be composed of a thermally insulating material. In thermally insulating examples of the support plate 34, the support plate 34 may be composed of a ceramic material such as aluminum oxide and other oxides. Use of thermally insulating examples of the support plate 34 may be advantageous in preventing heat bridging from occurring between the support substrate 14 and the optical element 22. Decreasing thermal bridging may be advantageous as regulating the net and local temperatures of the optical element 22 may allow for a more uniform deposition of the films and/or coatings.

The interface between the optical surface 22A and the support plate 34 may have sufficient friction such that sliding of the optical surface 22A on the support plate 34 generally does not occur. As such, as the optical mount 10 is heated, differences in the coefficient of thermal expansion between support substrate 14 and the optical element 22 may cause a stress to be generated at the contact point between the optical surface 22 and support plate 34 which may not be alleviated by sliding of the optical surface 22A across the support plate 34. Incorporation of the resilient member 30 may allow compression of the support plate 34 into the well 44 such that a stress generated due to the differences in coefficient of thermal expansion may be dissipated without damage to the optical element 22 and/or the support substrate 14. In other words, the resilient member 30 may allow the optical element 22 to expand in a radial direction without the generation of stresses which may damage the optical element 22.

The resilient member 30 is positioned below the support plate 34 within the well 44. The resilient member 30 is in contact with both the support plate 34 and the bottom surface 44A of the well 44. The resilient member 30 is configured to flex in response to relative motion between the optical element 22 and the support substrate 14. In other words, the resilient member 30 may be configured to elastically deflect and return to its original shape with the application and removal of force, respectively. The resilient member 30 is configured to flex in a direction normal to the surface (e.g., the support plate 34) of the contact location. In other words, the resilient member 30 allows flexing in a radial direction. Flexing of the resilient member 30 allows the support plate 34 to descend into the well 44 based on the relative motion of the optical element 22 and the support substrate 14. Such flexing of the resilient member 30 allows for dissipation of stress generated at the contact between the optical surface 22A and the support plate 34. The resilient member 30 may be a spring or other flexible member. In the depicted example, the resilient member 30 is a wave spring, but it will be understood that the resilient member 30 may take a variety of configurations as explained in greater detail below. For example, the resilient member 30 may be a compression spring. Further, the support plate 34 and the resilient member 30 may be integrally formed.

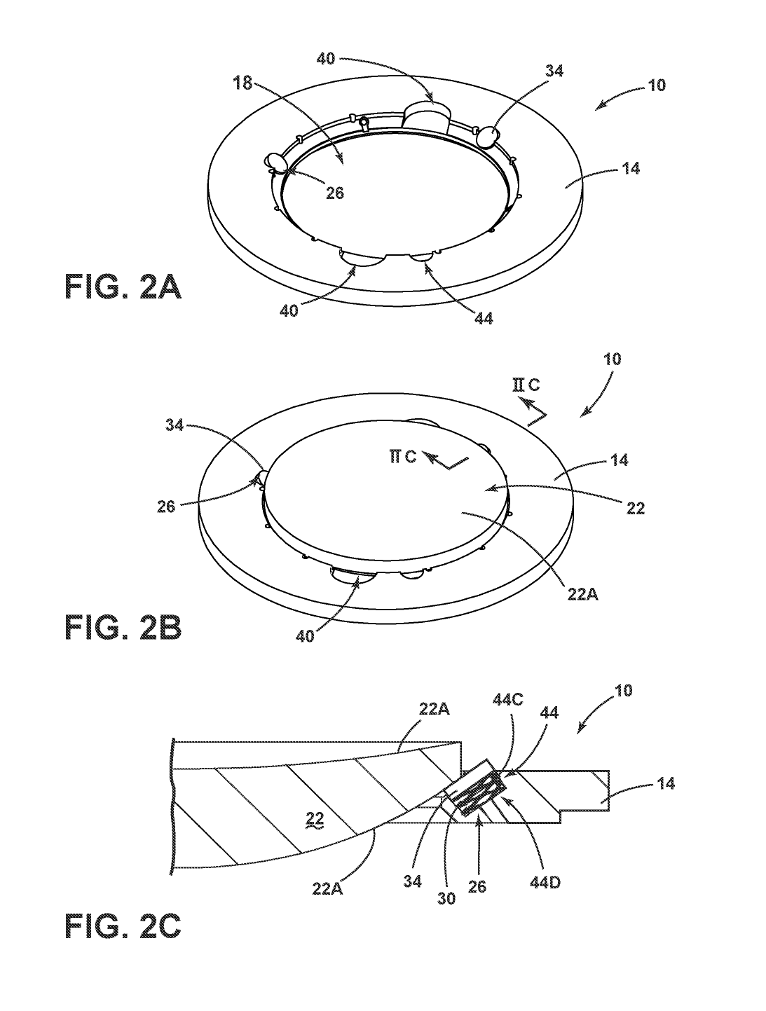

Referring now to FIGS. 2A-C, the resilient member 30 of the support assembly 26 is depicted as a stacked wave spring. A wave spring may be a spring made up of pre-hardened flat wire having waves which are added to give it a spring effect. In the depicted example, the well 44 defines both an upper portion 44C and a lower portion 44D. In such an example, the upper portion 44C may have a larger diameter than the lower portion 44D such that the well 44 is counterbored. The resilient member 30 may have a diameter substantially equal to that of the lower portion 44D of the well 44 while the support plate 34 has a diameter approximately equal to that of the upper portion 44C. The resilient member 30 may be positioned within the lower portion 44D. Such an example may be advantageous in securing the resilient member 30 in place while allowing a larger diameter support plate 34 to still move within the well 44.

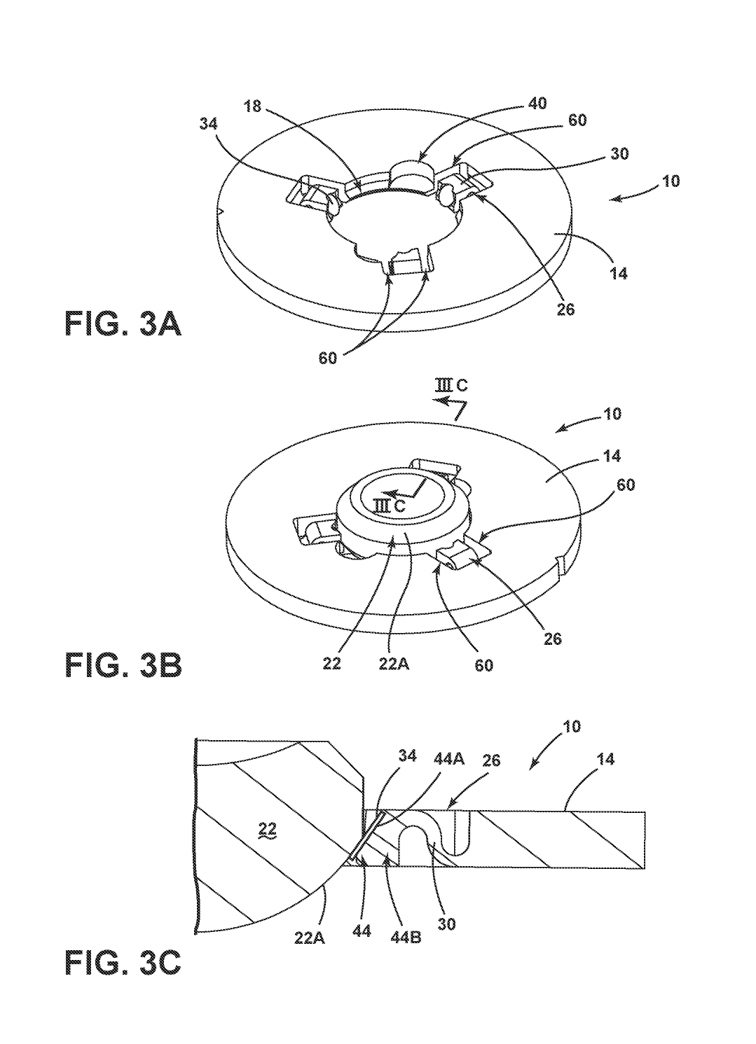

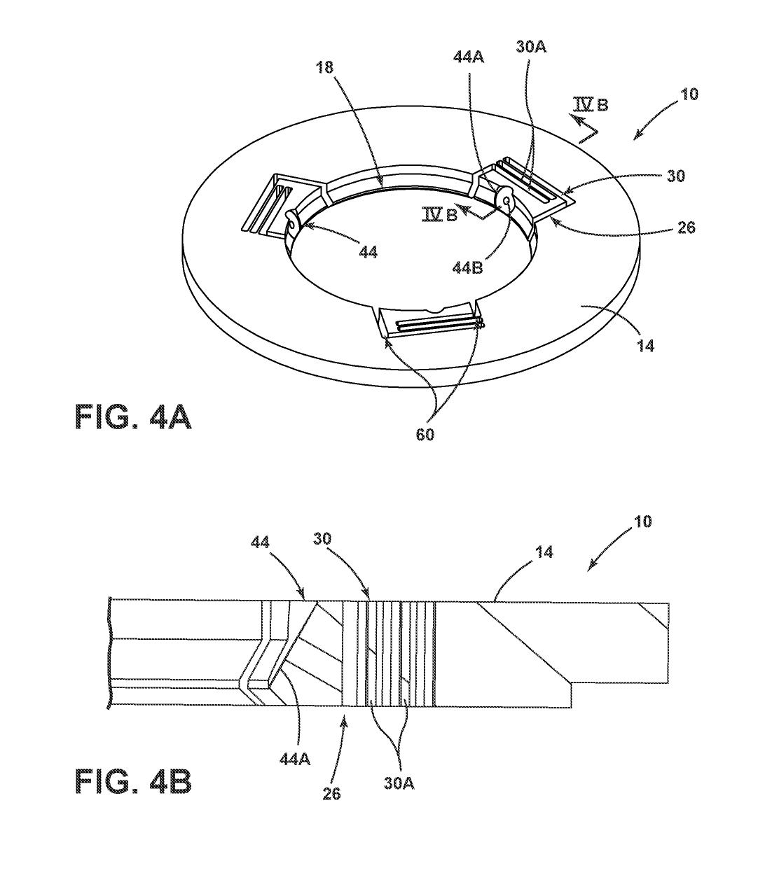

Referring now to FIGS. 3A-4C, the support assemblies 26 may not be positioned within the wells 44. For example, the resilient member 30 of the support assemblies 26 may be integrally defined by the support substrate 14. In such examples, the resilient members 30 may be known as “flexures.” According to one example, the resilient member 30 may be integrally formed from the support substrate 14 by forming the resilient member 30 at the time of making the support substrate 14 (e.g., casting, sintering, etc.). According to another example, the resilient member 30 may be formed from the support substrate 14 after the formation of the support substrate 18 (e.g., via machining, wire electro-discharge machining and/or other post-processing techniques). As explained above, the resilient member 30 is configured to flex in response to the relative motion of the optical element 22 and the support substrate 14 due to differences in coefficient of thermal expansion. In the depicted examples where the resilient member 30 is integrally defined by the support substrate 14, the resilient member 30 may still allow radial flexing to prevent the buildup of stress within the optical element 22. Gaps 60 may be defined on each side of the resilient member 30 to allow the resilient member 32 to flex in the same plane as the support substrate 14. In other words, the gaps 60 may allow the resilient member 32 to move in a side to side motion in addition to radially. One or more of the gaps 60 may extend the length of the resilient member 30.

In examples where the resilient members 30 are integrally defined by the support substrate 14, the resilient member 30 may define the wells 44. In other words, the resilient members 30 may be formed from the support substrate 14. In such an example, the support plates 34 may be positioned within the wells 44. In such an example, the support plate 34 is positioned on the bottom surface 44A of the well 44. As the support plate 34 is the contact point for the support substrate 14 to the optical element 22, flexing of the resilient member 30 due to relative motion between the optical element 22 and support substrate 14 may result in the well 44 moving as the resilient member 30 flexes. The resilient member 30 may be manufactured to increase the thermal resistance of the member 30 such that thermal bridging between the support substrate 14 and the optical element 22 is not achieved. It will be understood in the depicted examples, the channel 44B within the well 44 may be defined through the resilient member 30 to achieve the same benefits as described above.

Referring now to FIGS. 3A-3C, the resilient member 30 is integrally connected to, and formed from, the support substrate 14. The resilient member 30 is depicted is generally having an undulating, folded or wavy cross-section. The resilient member 30 may define a single undulation (i.e., as depicted) or a plurality of waves or undulations. The waves or undulations of the resilient member 30 may remain substantially within the plane of the support substrate 14, and/or the waves may extend above and below the support substrate 14. In other words, the waves or undulations of the resilient member 30 may have a greater amplitude than a thickness of the support substrate 14 such that the waves or undulations extend above and/or below the support substrate 14. Further, the resilient member 30 may include a plurality of separate bodies, each extending from the support substrate 14 to a portion proximate the well 44. In examples where the resilient member 30 includes a plurality of separate bodies, one or more of the bodies may include waves or undulations. In the depicted example, the resilient member 30 extends generally in a radially outward direction to couple with the support substrate 14, it will be understood that the resilient member 30 may take a variety of configurations without departing from the teachings provided herein.

Referring now to FIGS. 4A and 4B, the resilient member 30 is integrally defined by the support substrate 14 and defines a plurality of beams 30A. The plurality of beams 30A may be substantially parallel with one another and generally tangential to the perimeter of the aperture 18. In other words, the plurality of beams 30A may extend in a direction substantially perpendicular to a radially outward direction of the support substrate 14 and the aperture 18. It will be understood that resilient member 30 may include a single beam 30A without departing from the teachings provided herein. A spacing between each of the beams 30A may be substantially uniform or may vary across the resilient member 30. The plurality of beams 30A is configured to allow the support assembly 26 to flex in response to relative motion between the optical element 22 and the support substrate 14 due to differences in coefficient of thermal expansion.

It will be understood that in any of the configurations of the support assemblies 26, the well 44 and the resilient member 30 may be used interchangeably with one another. For example, the optical mount 10 may include one of each of the examples of the support assemblies 26 provided herein. In another example, the optical mount 10 may include three support assemblies 26, two of which are substantially similar (e.g., the example depicted in FIG. 1C) while the third is different (e.g., the example depicted in FIG. 4B).

The optical mount 10 may be used with an exemplary method. The method may begin with a step of positioning the optical element 22 on the support assembly 26 of the support substrate 14. The optical element 22 may be positioned on the thermally insulating support plate 34 of the support assembly 26. Next, a step of drawing a vacuum around the support substrate 14 and optical element 22 is performed. For example, the pressure around the support substrate 14 and the optical element 22 may be about 0.0001 mbar. Next, a step of heating the support substrate 14 and optical element 22 is performed. The optical element 22 and the support substrate 14 may be heated to greater than about 500° K. Next, a step of flexing the resilient member 30 of the support assembly 26 in response to relative motion between the optical element 22 and the support substrate 14 may be performed. For example, flexing of the resilient member 30 may permit flexing of the support plate 34 into the well 44 of the support substrate 14. Finally, a step of depositing a film on the optical surface 22A of the optical element 22 is performed. Additional steps of positioning the resilient member 30 within the well 44 of the support substrate 14, forming the resilient member 30 from the support substrate 14 (e.g., integrally defining), forming the resilient member 30 as a plurality of beams 30A from the support substrate 14, forming the gaps 60 between sides of the resilient member 30 and the support substrate 14 and positioning the support plate 34 within the well 44 may be performed. It will be understood that although described as discrete steps and in a specific order, the steps described above may be performed in any order and/or simultaneously with one another.

Use of the presently disclosed optical mount 10 may provide a variety of advantages. First, the optical mount 10 allows for differential expansion of the support substrate 14 and the optical element 22 throughout the temperature range of applying thin films. By allowing for differential expansion of the support substrate 14 and the optical element 22, a stress threshold for the optical element 22 and/or support substrate 14 may not be reached such that damage does not occur. Second, use of the support assemblies 26 may ease the manufacturing tolerances for the optical mount 10. For example, the optical element 22 and the support substrate 14 may not need to be exactly machined to account for differences in coefficient of thermal expansion.

Modifications of the disclosure will occur to those skilled in the art and to those who make or use the disclosure. Therefore, it is understood that the embodiments shown in the drawings and described above are merely for illustrative purposes and not intended to limit the scope of the disclosure, which is defined by the following claims, as interpreted according to the principles of patent law, including the doctrine of equivalents.

For purposes of this disclosure, the term “coupled” (in all of its forms: couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature, or may be removable or releasable in nature, unless otherwise stated.

What is claimed is:

1. An optical mount comprising:
a support substrate defining an aperture configured to receive an optical element; and
a support assembly positioned proximate a perimeter of the aperture, the support assembly, comprising:
a resilient member configured to flex in response to relative motion between the optical element and the support substrate; and
a support plate positioned on the resilient member and in contact with the optical element.

2. The optical mount of claim 1, wherein the support plate comprises a thermally insulating material.

3. The optical mount of claim 1, wherein the support substrate defines a well within which the support assembly is positioned.

4. The optical mount of claim 1, wherein the resilient member is a spring.

5. An optical mount comprising:
a support substrate defining an aperture configured to receive an optical element, wherein the support substrate defines a plurality of wells around a perimeter of the aperture; and
a support assembly positioned within each of the wells, the support assemblies comprising:
a support plate configured to contact the optical element; and
a resilient member configured to allow movement of the support plate within the well.

6. The optical mount of claim 5, wherein the support plate comprises a ceramic material.

7. The optical mount of claim 5, wherein the well is counterbored to define an upper portion and a lower portion, wherein the resilient member is positioned within the lower portion.

8. The optical mount of claim 5, wherein the resilient member is a wave spring.

9. An optical mount comprising:
a support substrate defining an aperture configured to receive an optical element; and
a plurality of support assemblies positioned around a perimeter of the aperture, the support assemblies, comprising:
a resilient member configured to flex in response to relative motion between the optical element and the support substrate, wherein the resilient member is integrally defined by the support substrate; and
a support plate positioned on the resilient member and in contact with the optical element.

10. The optical mount of claim 9, wherein the resilient member defines a plurality of beams.

11. The optical mount of claim 10, wherein the plurality of beams are substantially parallel with one another.

12. The optical mount of claim 11, wherein resilient member undulates between the support substrate and the support plate.

13. A method, comprising:
positioning an optical element on a support assembly of a support substrate;
drawing a vacuum around the support substrate and optical element;
heating the support substrate and optical element;
flexing a resilient member of the support assembly in response to relative motion between the optical element and the support substrate; and
depositing a film on an optical surface of the optical element.

14. The method of claim 13, further comprising the step:
positioning the optical element on a thermally insulating support plate of the support assembly.

15. The method of claim 13, further comprising the step:
flexing the support plate into a well of the support substrate.

16. The method of claim 13, further comprising the step:
positioning the resilient member within a well of the support substrate.

17. The method of claim 13, further comprising the step:
forming the resilient member from the support substrate.

18. The method of claim 13, further comprising the step:
forming the resilient member as a plurality of beams from the support substrate.

19. The method of claim 13, further comprising the step:
forming gaps between sides of the resilient member and the support substrate.

20. The method of claim 13, further comprising the step:
positioning the support plate within a well.
